(19) United States
(12) Patent Application Publication
(10) Pub. No.: US 2015/0069298 A1
(43) Pub. Date: Mar. 12, 2015

(54) SCINTILLATOR SINGLE CRYSTAL, HEAT TREATMENT PROCESS FOR PRODUCTION OF SCINTILLATOR SINGLE CRYSTAL, AND PROCESS FOR PRODUCTION OF SCINTILLATOR SINGLE CRYSTAL

(71) Applicant: HITACHI CHEMICAL COMPANY, LTD., Tokyo (JP)

(72) Inventors: Yasushi Kurata, Hitachinaka-shi (JP); Tatsuya Usui, Hitachi-shi (JP); Naoaki Shimura, Hitachinaka-shi (JP)

(73) Assignee: HITACHI CHEMICAL COMPANY, LTD., Tokyo (JP)

(21) Appl. No.: 14/543,542

(22) Filed: Nov. 17, 2014

Related U.S. Application Data
(63) Continuation of application No. 12/822,679, filed on Jun. 24, 2010.

(30) Foreign Application Priority Data
Jun. 29, 2009 (JP) 2009-154105
Apr. 28, 2010 (JP) 2010-103956

(51) Int. Cl. C09K 11/77; C30B 15/00; C30B 29/34; C30B 33/02

(52) U.S. Cl. CPC C09K 11/7792; C30B 33/02; C30B 15/00; C30B 29/34
USPC 252/301.4 F; 117/3; 117/19

(57) ABSTRACT

The scintillator single crystal of the invention comprises a cerium-activated orthosilicate compound represented by the following formula (1).

Gd_{2-(a+x+y+z)}LnₐLuₓCe_{y}Lm_{z}SiO₅ (1)

(In formula (1), Lm represents at least one element selected from among Pr, Tb and Tm, Ln represents at least one element selected from among lanthanoid elements excluding Pr, Tb and Tm, and Sc, and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

### CROSS-REFERENCE TO RELATED APPLICATIONS

This application is a Continuation of U.S. application Ser. No. 12/822,679, filed Jun. 24, 2010, which is based upon and claims the benefit of priority from the prior Japanese Patent Application No. 2009-154105 and Japanese Patent Application No. 2010-103956, filed on Jun. 29, 2009 and Apr. 28, 2010, respectively, the entire contents of which are incorporated herein by reference.

### BACKGROUND OF THE INVENTION

1. Field of the Invention

The present invention relates to a scintillator single crystal used in a single-crystal scintillation detector (scintillator) for gamma ray or other radiation in the fields of radiology, physics, physiology, chemistry, mineralogy and oil exploration, such as for medical diagnostic positron CT (PET), cosmic radiation observation, underground resource exploration and the like, as well as to a heat treatment process for production of a scintillator single crystal and to a process for production of a scintillator single crystal. More specifically, the invention relates to a scintillator single crystal comprising a cerium-activated orthosilicate compound, to a heat treatment process for production of a scintillator single crystal, and to a process for production of a scintillator single crystal.

2. Related Background Art

Scintillators composed of gadolinium orthosilicate compounds with cerium as the activator have short fluorescent decay times and large radiation absorption coefficients, and are therefore employed as radiation detectors for positron CT (hereunder, “PET”) and the like. However, while such scintillators have higher fluorescent output than BGO scintillators, it is only about 20% of that of a NaI (Tl) scintillator and is therefore in need of further improvement.

Scintillators employing single crystals of cerium-activated lutetium orthosilicates represented by the formula Lu₂₍₁₋ₓ₎Ce₂ₓSiO₅ (see Japanese Patent Publication No. 2852944 and U.S. Pat. No. 4,958,080, for example), scintillators employing single crystals of cerium-activated lutetium orthosilicate gadolinium represented by the formula Gd_{2-(x+y)}LnₓCe_{y}SiO₅ (where Ln is at least one element selected from the group consisting of Sc, Tb, Dy, Ho, Er, Tm, Yb and Lu) (see Japanese Examined Patent Publication HEI No. 7-78215 and U.S. Pat. No. 5,264,154, for example), and scintillators employing single crystals of cerium-activated lutetium yttrium orthosilicate represented by the formulas Ce₂ₓ(Lu_{1-y}Y_{y})SiO₅ and Ce₂ₓ(Lu_{1-y}Y_{y})_{2 (1-x)}SiO₅ (see U.S. Pat. No. 6,624,420 and U.S. Pat. No. 6,921,901, for example), are known. Not only are such scintillators known to have improved crystal density, but the fluorescent output of cerium-activated orthosilicate compound single crystals are known to be superior and the fluorescent decay times shorter.

It is known that single crystals of cerium-activated lutetium orthosilicate represented by Ln_{2-(x+y)}LuₓCe_{y}SiO₅ (where Ln is at least one element selected from the group consisting of Sc, Tb, Dy, Ho, Er, Tm, Yb and Lu, and including Y) can yield scintillators with different fluorescent decay times by varying the cerium concentration in the activator.

The continuing development of PET in recent years has led to expectations for development of next-generation high performance PET that combines scintillators with different fluorescent decay times, and scintillators with high fluorescent output, excellent energy resolution, low fluorescent output difference and low variation in properties are in demand.

However, varying the cerium concentration of the activator not only alters the fluorescent decay time but also lowers the fluorescent output or energy resolution, leading to variation in the scintillator properties.

The variation in the properties is attributed not only to the cerium concentration but also oxygen deficiency within the crystal lattice. Presumably, the oxygen deficiency results in formation of an energy trap level, creating an increased fluorescent output background (afterglow) due to the effect of thermal excitation from that level, and increasing fluorescent output variation.

Japanese Unexamined Patent Publication No. 2006-199727 describes a Ce and Tm co-activated lutetium silicate single crystal as a cerium-activated lanthanoid silicate scintillator single crystal represented by the formula Ce₂ₓLn_{2y}Lu_{2(1-x-y)}SiO₅ (where Ln is any element from among lanthanoid elements except for Lu, and 2×10⁻⁴≦x≦3×10⁻², 1×10⁻⁴≦y≦1×10⁻³), and it is stated that this improves variation in fluorescent output, decay time and energy resolution within ingots depending on the vertical position.

Also, Japanese Unexamined Patent Publication HEI No. 2-64008 describes a scintillator comprising a lanthanide silicate single crystal represented by the formula (Ln₁₋ₓ₁₋₂₋ₓ₃Ln′ₓ₁Ceₓ₂Tbₓ₃)_{9.33}(SiO₄)₆O₂ (where Ln and Ln′ are different and represent rare earth elements selected from among La, Gd, Yb and Lu, and x₁, x₂ and x₃ are such that 0<x₁<1, 0<x₂<0.05, 0<x₃<0.05, 0<x₂+x₃<0.1 and 0<x₁+x₂+x₃<1), and states that the obtained scintillator exhibits more satisfactory performance than those obtained using known oxyorthosilicates.

### SUMMARY OF THE INVENTION

DOI (Depth of Interaction)-type next-generation high performance PET, employing a system combining scintillators with different fluorescent decay times, requires characteristics with a specific decay time difference and a low difference in fluorescent output or energy resolution. The fluorescent decay time in a cerium-activated lutetium orthosilicate compound single crystal can be adjusted by varying the cerium concentration in the starting material, and this has been studied for application in high performance DOI PET scintillators. However, since the fluorescent output is reduced at the low cerium concentration end which has a short fluorescent decay time, the difference in output compared to a scintillator with a long fluorescent decay time combination is problematic from the standpoint of pulse shape discrimination of the energy spectrum. A cerium-activated lutetium orthosilicate compound must therefore have low cerium concentration-dependence for the fluorescent output.

Incidentally, although Japanese Unexamined Patent Publication No. 2006-199727 describes the effect of limiting the variation in properties of the upper and lower sections of the crystals in the ingot to no greater than 15%, it does not mention the differences in characteristics between ingots with different cerium concentrations in the starting material.

According to the first aspect of the present invention, which has been accomplished in light of the aforementioned problems of the prior art, it is an object to provide a scintillator single crystal that can sufficiently reduce the difference in fluorescent output between the cerium low concentration and high concentration ends. It is another object, according to the first aspect of the invention, to provide a heat treatment process for production of a scintillator single crystal that can sufficiently reduce the difference in fluorescent output between the cerium low concentration and high concentration ends, as well as a process for production of the scintillator single crystal.

According to the second aspect of the invention, which has also been accomplished in light of the aforementioned problems of the prior art, it is an object to provide scintillator single crystals with sufficiently long fluorescent decay times so that the difference in fluorescent decay times between two different scintillators that are combined is 10 ns or greater, as well as a method for producing them.

The first aspect of the invention provides a scintillator single crystal comprising a cerium-activated orthosilicate compound represented by the following formula (1).

Gd_{2-(a+x+y+z)}LnₐLuₓCe_{y}Lm_{z}SiO₅ (1)

(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

The scintillator single crystal according to the first aspect of the invention can sufficiently reduce differences in fluorescent output between the cerium low concentration and high concentration ends, since it has a construction comprising a cerium-activated orthosilicate compound represented by formula (1). With a scintillator single crystal of the invention wherein at least one element selected from among Pr, Tb and Tm is added to a cerium-activated orthosilicate compound single crystal for coactivation with cerium, it is possible to improve the fluorescent output and energy resolution particularly at the cerium low concentration end, and sufficiently reduce the difference in fluorescent output and energy resolution between the cerium low concentration and high concentration ends.

In a scintillator single crystal according to the first aspect of the invention, more preferably Ln is Gd, a represents a value of greater than 0 and less than 1, and Lm is at least one element selected from Tb and Tm. On the other hand, when the Pr concentration is higher than optimal, it interacts with Gd so that the fluorescent wavelength is detected slightly toward the short wavelength end, thus reducing the degree of improvement in the fluorescent output or energy resolution of the scintillator single crystal.

In a scintillator single crystal according to the first aspect of the invention, preferably Ln is Y, and a represents a value of greater than 0 and less than 1. When Ln is Y, strain on the crystal structure of the LSO matrix structure is low and the fluorescent output or energy resolution can thus be improved.

Also, in a scintillator single crystal according to the first aspect of the invention, preferably Ln is Y, a represents a value of greater than 0 and no greater than 0.2, and x represents a value of greater than 1.6 and less than 2. When Ln is Y and the values of a and x are within these ranges, strain on the crystal structure of the LSO matrix structure is low and the fluorescent output or energy resolution can thus be improved.

A scintillator single crystal according to the first aspect of the invention preferably contains an added element, which is at least one element selected from among elements belonging to Group 2 (Group IIa) of the Periodic Table, at 0.00005-0.1 mass % based on the total mass of the single crystal. This can still further reduce reduction or variation in the fluorescent properties thought to be due to oxygen defects, and thus improve the fluorescent properties of the single crystal while reducing the fluorescent output background (afterglow) caused by crystal defects.

A scintillator single crystal according to the first aspect of the invention preferably contains an added element, which is at least one element selected from among elements belonging to Group 13 (Group IIIb) of the Periodic Table, at 0.00005-0.1 mass % based on the total mass of the single crystal. This can provide a notable effect of improving the fluorescent properties of the single crystal while reducing the fluorescent output background (afterglow) caused by crystal defects. A still higher effect can be achieved by the simultaneous presence of one or more added elements selected from among elements belonging to Group 2 of the Periodic Table.

The first aspect of the invention is a heat treatment process for production of a scintillator single crystal, which is a heat treatment process in which a single crystal body is grown using a starting material comprising the constituent element for a scintillator single crystal containing a cerium-activated orthosilicate compound represented by the following formula (1), and is heat treated at a temperature of 700-1500° C. in an oxygen-containing atmosphere.

Gd_{2-(a+x+y+z)}LnₐLuₓCe_{y}Lm_{z}SiO₅ (1)

(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

According to this heat treatment process it is possible to provide a scintillator single crystal that can reduce variation in the elemental distribution within a single crystal (single crystal ingot) due to the phenomenon of segregation between elements, and that can minimize afterglow and property deterioration attributed to oxygen defects, and thereby sufficiently reduce the difference in fluorescent output between the cerium low concentration and high concentration ends. According to this heat treatment process it is also possible to provide a scintillator single crystal with improved fluorescent output and energy resolution particularly at the cerium low concentration end which has a short decay time.

The first aspect of the invention further provides a process for production of a scintillator single crystal, which comprises a step of preparing a starting material comprising the constituent element for a scintillator single crystal containing a cerium-activated orthosilicate compound represented by the following formula (1), and growing a single crystal body by the Czochralski method, and a step of heat treating the single crystal body at a temperature of 700-1500° C. in an oxygen-containing atmosphere.

Gd_{2-(a+x+y+z)}LnₐLuₓCe_{y}Lm_{z}SiO₅ (1)

(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

According to this production process, it is possible to provide a process for production of a scintillator single crystal that can reduce cracking and other problems during crystal growth due to the phenomenon of segregation between elements, not only improving the fluorescent properties but also minimizing afterglow and deterioration in properties that is attributed to oxygen defects, and that can sufficiently reduce the difference in fluorescent output between the cerium low concentration and high concentration ends. According to this production process it is also possible to provide a process for production of a scintillator single crystal with improved fluorescent output and energy resolution particularly at the cerium low concentration end which has a short decay time.

The second aspect of the invention provides a scintillator single crystal comprising a cerium-activated orthosilicate compound represented by the following formula (2), which contains at least one added element selected from among elements belonging to Group 2 (group IIa) of the Periodic Table at 0.00005-0.1 mass % based on the total mass of the single crystal, and wherein the ratio of the fluorescence intensity at an excitation wavelength of 364 nm with respect to the fluorescence intensity at an excitation wavelength of 304 nm (364 nm/304 nm), at a fluorescent wavelength of 420 nm, is less than 3.

Gd_{2-(a+x+y+z)}LnₐLuₓCe_{y}Lm_{z}SiO₅ (2)

(In formula (2), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0.01 and no greater than 0.03, and z represents a value of at least 0 and no greater than 0.01. The value of a+x+y+z is no greater than 2.)

The scintillator single crystal according to the second aspect of the invention can produce a sufficiently long fluorescent decay time to easily allow the difference in fluorescent decay times of two different scintillators that are combined to be 10 ns or greater, since it has a construction comprising a cerium-activated orthosilicate compound represented by formula (2).

The second aspect of the invention further provides a process for production of a scintillator single crystal, which comprises a step of preparing a starting material comprising the constituent element for a scintillator single crystal containing a cerium-activated orthosilicate compound represented by the following formula (2), and growing a single crystal body by the Czochralski method.

Gd_{2-(a+x+y+z)}LnₐLuₓCe_{y}Lm_{z}SiO₅ (2)

(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0.01 and no greater than 0.03, and z represents a value of at least 0 and no greater than 0.01. The value of a+x+y+z is no greater than 2.)

According to this production process, it is possible to produce a scintillator single crystal with a sufficiently long fluorescent decay time to easily allow the difference in fluorescent decay times between two different scintillators that are combined to be 10 ns or greater.

According to the first aspect of the present invention, it is possible to provide a scintillator single crystal that can sufficiently reduce the difference in fluorescent output between the cerium low concentration and high concentration ends. Also according to the first aspect of the invention, it is possible to provide a scintillator single crystal with improved fluorescent output and energy resolution particularly at the cerium low concentration end which has a short decay time. According to the first aspect of the invention it is also possible to provide a heat treatment process for production of a scintillator single crystal that can sufficiently reduce the difference in fluorescent output between the cerium low concentration and high concentration ends, as well as a process for production of the scintillator single crystal.

According to the second aspect of the invention it is possible to provide a scintillator single crystal with a sufficiently long fluorescent decay time to easily allow the difference in fluorescent decay times between two different scintillators that are combined to be 10 ns or greater, as well as a process for production of the same.

### BRIEF DESCRIPTION OF THE DRAWINGS

FIG. 1 is a schematic cross-sectional view showing an example of the basic construction of a growth apparatus used for growth of a scintillator single crystal according to the first and second aspects of the invention.

FIG. 2 shows fluorescence spectra at an excitation wavelength of 364 nm, for the scintillator single crystals obtained in the examples and comparative examples. Each spectrum is represented with a maximum output value of 1.

FIG. 3 shows excitation wavelength spectra at a fluorescent wavelength of 420 nm, for the scintillator single crystals obtained in the examples and comparative examples.

### DESCRIPTION OF THE PREFERRED EMBODIMENTS

Preferred embodiments of the invention will now be described in detail. Through the following explanation, a preferred embodiment of the first aspect of the invention will be referred to as the “first embodiment”, and a preferred embodiment of the second aspect of the invention will be referred to as the “second embodiment”.

The scintillator single crystal of the first embodiment comprises a cerium-activated orthosilicate compound represented by the following formula (1).

Gd_{2-(a+x+y+z)}LnₐLuₓCe_{y}Lm_{z}SiO₅ (1)

(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

When the value of a+x+y+z in formula (1) is 2, formula (1) becomes the following formula (3).

Ln_{2-(x+y+z)}LuₓCe_{y}Lm_{z}SiO₅ (3)

(In formula (3), Ln represents at least one element selected from among lanthanoid elements excluding Pr, Tb and Tm and including Lu, and Sc and Y, Lm represents at least one element selected from among Pr, Tb and Tm, x represents a value of greater than 1 and less than 2, y represents a value of greater than 0 and no greater than 0.01, and z represents a value of greater than 0 and no greater than 0.01. The value of x+y+z is no greater than 2.)

Since x, y and z in formula (3) are in the ranges specified above in the scintillator single crystal comprising a cerium-activated orthosilicate compound represented by formula (3), it is possible to obtain fluorescent output with a short fluorescent decay time at room temperature.

A larger value for x in formula (3) increases the crystal density and results in high fluorescent output at room temperature. Therefore, the value of x must be greater than 1 and less than 2, preferably 1.2 or greater and less than 2, more preferably 1.4 or greater and less than 2, and even more preferably 1.6 or greater and less than 2.

The value of y in formula (3) must be greater than 0 and no greater than 0.01, and is preferably 0.00005 or greater and no greater than 0.01, more preferably 0.0001 or greater and no greater than 0.01, even more preferably 0.0002 or greater and no greater than 0.005, and most preferably 0.0005 or greater and no greater than 0.003. If y is 0 it will not be possible to obtain sufficient fluorescent output, and if it exceeds 0.01 coloration of the crystal in the oxygen-containing heat treatment step after growth will be notable, reducing the fluorescent output.

The value of z in formula (3) must be greater than 0 and no greater than 0.01, and is preferably greater than 0 and less than 0.01, more preferably 0.0001 or greater and no greater than 0.005, even more preferably 0.0001 or greater and no greater than 0.004, and most preferably 0.0002 or greater and no greater than 0.001. If z is 0 the fluorescent output will be reduced, and if it exceeds 0.01 the crystal coloration will be notable, the fluorescent output will be reduced and strain in the crystal will lead to cracking.

Gd becomes an essential element if the value of a+x+y+z in formula (1) is less than 2. In this case as well, the scintillator single crystal has a, x, y and z in formula (1) in the ranges specified above, and therefore it is possible to obtain fluorescent output with a short fluorescent decay time at room temperature.

If the value of a+x+y+z is less than 2, a in formula (1) is preferably 0 or greater and no greater than 0.5, more preferably greater than 0 and no greater than 0.5, even more preferably greater than 0 and no greater than 0.4, yet more preferably greater than 0 and no greater than 0.2, and most preferably greater than 0.05 and no greater than 0.2. If a is greater than 0.5, the crystal structure will be under strain and cracking within the crystal will tend to increase. When a is 0, it becomes difficult to prevent segregation of Gd and a lower fluorescent property may result.

The preferred ranges for the values of x, y and z in formula (1) are the same as the preferred ranges for x, y and z in formula (3), respectively.

The scintillator single crystal of the second embodiment comprises a cerium-activated orthosilicate compound represented by the following formula (2).

Gd_{2-(a+x+y+z)}LnₐLuₓCe_{y}Lm_{z}SiO₅ (2)

(In formula (2), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0.01 and no greater than 0.03, and z represents a value of at least 0 and no greater than 0.01. The value of a+x+y+z is no greater than 2.)

Since a, x, y and z in formula (2) are within the ranges specified above for a scintillator single crystal represented by formula (2), the fluorescent property at room temperature is excellent, and in particular it is possible to obtain superior characteristics in combination with a semiconductor detector having excellent sensitivity for long-wavelength light of 500 nm and greater such as from an avalanche photodiode.

The value of y in formula (2) must be greater than 0.01 and no greater than 0.03, and is preferably greater than 0.01 and less than 0.03, more preferably greater than 0.01 and no greater than 0.025, even more preferably 0.012 or greater and no greater than 0.02, and most preferably 0.012 or greater and no greater than 0.018. If y is 0.01 or smaller it will not be possible to obtain sufficient fluorescent output with semiconductor detectors having excellent sensitivity for fluorescent wavelengths of 500 nm and longer, and if it is greater than 0.03 the grown crystal will exhibit notable coloration and the fluorescent output may be reduced, resulting in increased cracking of the crystal.

The value of z in formula (2) must be 0 or greater and no greater than 0.01, and is preferably 0 or greater and less than 0.01, more preferably 0.0001 or greater and no greater than 0.005, even more preferably 0.0001 or greater and no greater than 0.004, and most preferably 0.0001 or greater and no greater than 0.001. The fluorescent output will not be a problem with a value of less than 3 for the ratio of the fluorescence intensity at an excitation wavelength of 364 nm with respect to the fluorescence intensity at an excitation wavelength of 304 nm (364 nm/304 nm), with a fluorescent wavelength of 420 nm which is approximately the maximum fluorescent output even when z is 0, but if z exceeds 0.01 the crystal will exhibit notable coloration and reduced fluorescent output and cracking due to strain in the crystal.

The preferred ranges for the values of a and x in formula (2) are each the same preferred ranges for the values of a and x in formula (1), for the same reason explained for formula (1).

In formulas (1), (2) and (3), Ln is at least one element selected from among lanthanoid elements excluding Pr, Tb and Tm, and Sc and Y. More preferably, it is at least one element selected from among Sc and Y and lanthanoid elements with ion radii larger than Dy and no larger than Lu. When the matrix structure is LGSO, the ingot lower part will tend to become turbid due to segregation of Gd, lowering the fluorescent property, but by including at least one element selected from among Sc and Y and lanthanoid elements with ion radii relatively close to that of Lu or smaller than Lu, segregation of Gd is inhibited and turbidity of the ingot lower part is eliminated, thus preventing reduction in the fluorescent property. Of these elements, Sc, Y and Yb are more preferred since they allow relatively easy single crystal growth even when abundantly present in the crystal, and Y is most preferred from the viewpoint of obtaining an effect without impairing the fluorescent property, and of improving the fluorescent property.

The scintillator single crystal according to the first embodiment preferably contains an added element which is at least one element selected from among elements belonging to Group 2 (Group IIa) of the Periodic Table. This can reduce loss and variation of the fluorescent property believed to be caused by oxygen defects, and can reduce the fluorescent output background (afterglow) resulting from crystal defects. The added element content is preferably 0.00005-0.1 mass % and more preferably 0.005-0.02 mass % based on the total mass of the scintillator single crystal, to allow the aforementioned effect to be more satisfactorily obtained. Among elements belonging to Group 2 (Group IIa) of the Periodic Table, one or more elements selected from among Ca and Mg are preferably included as elements to allow the aforementioned effect to be more satisfactorily obtained.

The scintillator single crystal according to the second embodiment contains an added element, which is at least one element selected from among elements belonging to Group 2 (Group IIa) of the Periodic Table, at 0.00005-0.1 mass % based on the total mass of the scintillator single crystal. This can reduce loss and variation of the fluorescent property believed to be caused by oxygen defects, and can reduce the fluorescent output background (afterglow) resulting from crystal defects. In addition, as an effect of adding an element belonging to Group 2 (Group IIa) of the Periodic Table, it is possible to inhibit crystal coloration and fluorescent output reduction due to change in the valency of Ce (Ce³⁺→Ce⁴⁺) as a result of trace oxygen in the growth atmosphere during crystal growth. This effect tends to be more notable with a high Ce concentration, and since it was also found that the change in valency of Ce (Ce³⁺→Ce⁴⁺) forms crystal defects similar to oxygen defects, an effect of further reducing the fluorescent output background (afterglow) is obtained. The added element content must be 0.00005-0.1 mass % and is preferably 0.005-0.02 mass % based on the total mass of the scintillator single crystal, to allow the aforementioned effect to be more satisfactorily obtained. Among elements belonging to Group 2 (Group IIa) of the Periodic Table, one or more elements selected from among Ca and Mg are preferably included as elements to allow the aforementioned effect to be more satisfactorily obtained.

The scintillator single crystals according to the first and second embodiments preferably contain an added element which is at least one element selected from among elements belonging to Group 13 (Group IIIb) of the Periodic Table. This can provide an even more notable effect of reducing the fluorescent output background (afterglow) believed to be caused by crystal defects. The added element content is preferably 0.00005-0.1 mass % and more preferably 0.005-0.02 mass % based on the total mass of the scintillator single crystal, to allow the aforementioned effect to be more satisfactorily obtained. A higher effect may be obtained by including the added elements simultaneously with the one or more added elements selected from among Ca and Mg among elements belonging to Group 2 (Group IIa) of the Periodic Table. Such elements are preferably one or more elements selected from among Al, Ga and In, among elements belonging to Group 13 (Group IIIb) of the Periodic Table, to allow the aforementioned effect to be more satisfactorily obtained.

Also, in the scintillator single crystal according to the first or second embodiment, the total concentration of the one or more elements selected from among elements belonging to Groups 4, 5 and 6 and Groups 14, 15 and 16 of the Periodic Table is preferably no greater than 0.002 mass % based on the total mass of the scintillator single crystal of the first or second embodiment. This can inhibit deterioration in the fluorescent property.

In the scintillator single crystal of the first embodiment, comprising a cerium-activated orthosilicate compound represented by formulas (1) and (3), the ratio of the fluorescence intensity at an excitation wavelength of 364 nm with respect to the fluorescence intensity at an excitation wavelength of 304 nm (364 nm/304 nm), at a fluorescent wavelength of 420 nm, at which the fluorescent output is approximately maximum, is preferably at least 10, more preferably at least 20 and most preferably at least 30. This can provide an effect of further shortening the fluorescent decay time while maintaining high fluorescent output.

On the other hand, in the scintillator single crystal of the second embodiment, which comprises a cerium-activated orthosilicate compound represented by formula (2), the ratio of the fluorescence intensity at an excitation wavelength of 364 nm with respect to the fluorescence intensity at an excitation wavelength of 304 nm (364 nm/304 nm), at a fluorescent wavelength of 420 nm, at which the fluorescent output is approximately maximum, is less than 3 and preferably less than 2. This will slightly increase the fluorescent decay time, but will also increase the long wavelength component near 500 nm among the fluorescent wavelengths, thus allowing improvement in the energy conversion efficiency for semiconductor photodetectors having maximum sensitivity of 500 nm or longer, such as avalanche photodiodes.

The scintillator single crystal of the first embodiment is produced by a step of growing a single crystal body using a starting material comprising the constituent element for a scintillator single crystal containing a cerium-activated orthosilicate compound represented by formula (1) or (3), and heat treating it in an oxygen-containing atmosphere (hereunder referred to as “heat treatment step”). By this heat treatment step it is possible to reduce variation in fluorescent output caused by the oxygen deficiency mentioned above. In other words, heat treatment of the single crystal body at the lower temperature end in an oxygen-containing atmosphere can sufficiently reduce oxygen deficiency without conversion of the trivalent cerium ion to tetravalent ion. As a result, the single crystal obtained through this heat treatment process has reduced background (afterglow) without exhibiting lower fluorescent output, and variation in the fluorescent output can be minimized, thus allowing a more satisfactory fluorescent property to be realized.

The oxygen-containing atmosphere has an oxygen concentration of at least 1 vol % and no greater than 100 vol %, and preferably the atmosphere contains nitrogen or an inert gas (for example, an air atmosphere). An atmosphere with an oxygen concentration of 30 vol % or greater is preferred, and an atmosphere with an oxygen concentration of 50 vol % or greater is especially preferred. With an oxygen concentration of less than 1 vol %, the oxygen partial pressure is low and the oxygen does not readily diffuse in the crystal, making it difficult to obtain the effect of the first embodiment. Since a higher oxygen concentration is preferred, a method using a closed furnace for circulation of oxygen at a constant flow rate is effective.

The heating temperature for the single crystal body in the heat treatment step is 700° C.-1500° C. and preferably 1000° C.-1300° C. With a heating temperature of below 700° C. it becomes difficult to obtain the aforementioned effect of the first embodiment, and with a temperature of higher than 1500° C. the cerium ion will tend to be converted to tetravalent ion, resulting in coloration of the single crystal and lower fluorescent output.

If the heat treatment process described above is applied to a single crystal body grown using a starting material comprising the constituent element for a scintillator single crystal containing a cerium-activated orthosilicate compound represented by formula (1) or (3), it becomes possible to absolutely minimize oxygen deficiency, reduce background (afterglow) and maximize improvement in fluorescent output and energy resolution.

In contrast, when a step of growing a single crystal body using a starting material comprising the constituent element for a scintillator single crystal containing a cerium-activated orthosilicate compound represented by formula (2), and heat treating it in an oxygen-containing atmosphere, is employed in the production of a scintillator single crystal according to the second embodiment, conversion of trivalent cerium ion to tetravalent ion becomes notable, potentially impairing the fluorescent property. The “heat treatment step” described above is therefore unsuitable for the second embodiment.

Examples of processes for production of scintillator single crystals according to the first and second embodiments will now be explained.

In the process for production of a scintillator single crystal according to the first or second embodiment, first the starting material for the cerium-activated orthosilicate compound represented by formula (1) or (2) is mixed to the prescribed stoichiometric composition and loaded into a crucible. The starting material for production of the single crystal may be a simple oxide and/or complex oxide of Gd, Lu, Si, Pr, Tb, Tm or Ce, as constituent elements of the one or more cerium-activated orthosilicate compounds selected from among praseodymium, terbium and thulium represented by formula (1). Preferred commercially available products for use include high-purity products by Shin-Etsu Chemical Co., Ltd., Stanford Materials Corp., Tama Chemicals Co., Ltd. and Nippon Yttrium Co., Ltd.

When the single crystal contains an element belonging to Group 2 (Group IIa) of the Periodic Table and/or an element belonging to Group 13 (Group IIIb) of the Periodic Table, the timing for addition of these added elements is not particularly restricted so long as it is before the crystal growth. For example, even when the added elements are added and mixed when weighing out the starting material, an element belonging to Group 2 (Group IIa) of the Periodic Table and/or an element belonging to Group 13 (Group IIIb) of the Periodic Table may be combined while loading the starting material into the crucible. The form of the added elements during addition is not particularly restricted so long as they are included in the grown single crystal, and they may be added to the starting material as oxides or carbonates, for example.

The crucible filled with the starting material is then heated to melt the starting material (melting step), and the molten fluid is subsequently subjected to cooling solidification (cooling solidification step) to obtain a single crystal ingot.

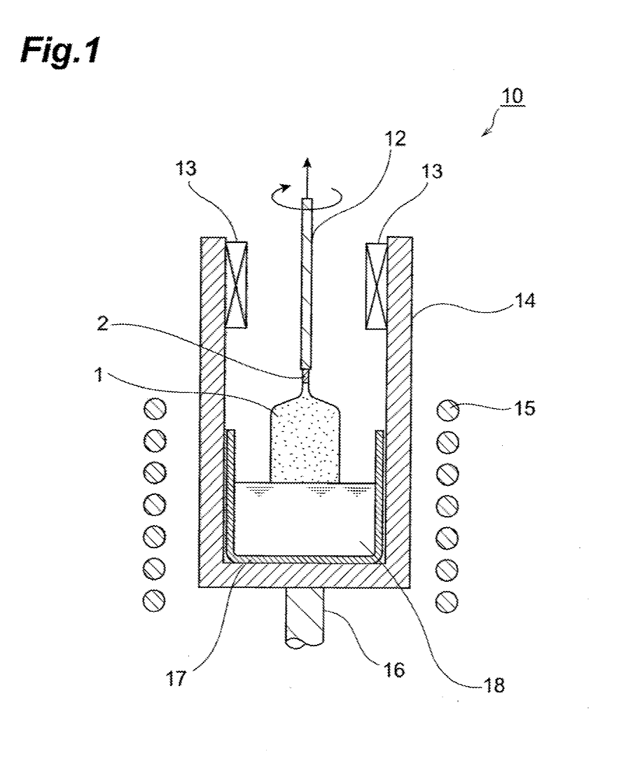

The melting process in the melting step may be based on the Czochralski method or another method. When the melting step is carried out by the Czochralski method, a lifting apparatus 10 having the construction shown in FIG. 1 is preferably used for the operation in the melting step and cooling solidification step.

FIG. 1 is a schematic cross-sectional view of an example of the basic construction of a growth apparatus for growth of a single crystal by the production method according to the first and second embodiments. The lifting apparatus 10 shown in FIG. 1 has a high-frequency induction heating furnace 14. The high-frequency induction heating furnace 14 is used for continuous operation in the melting step and the cooling solidification step described above.

The high-frequency induction heating furnace 14 is a refractory cylindrical walled, closed-bottom vessel, and the shape of the closed-bottom vessel is the same as one used for single crystal growth based on the publicly known Czochralski method. A high-frequency induction coil 15 is wound on the outside of the bottom of the high-frequency induction heating furnace 14. Also, a crucible 17 (for example, a crucible made of Ir) is set on the bottom inside the high-frequency induction heating furnace 14. The crucible 17 also serves as a high-frequency induction heater. The starting material for the single crystal is loaded into the crucible 17, and application of high-frequency induction to the high-frequency induction coil 15 heats the crucible 17 and produces a melt 18 composed of the constituent material of the single crystal.

At the center bottom of the high-frequency induction heating furnace 14 there is provided an opening (not shown) which passes from the inside to the outside of the high-frequency induction heating furnace 14. Through this opening there is inserted a crucible support rod 16, from the outside of the high-frequency induction heating furnace 14, and the end of the crucible support rod 16 is connected to the bottom of the crucible 17. Rotating the crucible support rod 16 allows the crucible 17 to be rotated in the high-frequency induction heating furnace 14. The area between the opening and the crucible support rod 16 is sealed with packing or the like.

A more specific production process using a lifting apparatus 10 will now be explained.

First, in the melting step, the starting material for the single crystal is loaded into the crucible 17 and high-frequency induction is applied to the high-frequency induction coil 15 to obtain a melt 18 composed of the constituent material for the single crystal.

Next, in the cooling solidification step, the melt is cooled to solidification to obtain a cylindrical single crystal ingot 1. More specifically, the operation proceeds through two separate steps, the crystal growth step described below and a cooling step.

First in the crystal growth step, a lifting rod 12 having a seed crystal 2 affixed to its lower end is loaded into the melt 18 from the top of the high-frequency induction heating furnace 14, and then the lifting rod 12 is lifted while forming a single crystal ingot 1. During this time, the heating output from the heater 13 is adjusted in the crystal growth step, so that the single crystal ingot 1 raised from the melt 18 grows to have a cross-section with the prescribed diameter.

Next, in the cooling step, the heating output of the heater is adjusted for cooling of the grown single crystal ingot obtained after the crystal growth step.

In the production process according to the first and second embodiments, the crystal growth atmosphere preferably contains oxygen in a range of 0-0.6 vol %. If the oxygen concentration exceeds 0.6 vol %, the fluorescent output may be reduced by coloration or the like. When an iridium crucible is used, the evaporation loss due to oxidation of the iridium crucible becomes a problem.

Also, in the production process according to the first embodiment, heat treatment is carried out in an oxygen-containing atmosphere after growth or after growth and working of the single crystal (heat treatment step). An effect of increased fluorescent output is obtained as a result of reduced coloration during heat treatment. The heat treatment temperature is suitably 700° C.-1500° C. to facilitate the effect mentioned above.

For the single crystal in the production process according to the first embodiment, praseodymium, terbium or thulium is added to the cerium-activated orthosilicate compound single crystal for coactivation with cerium, and preferably an element belonging to Group 2 (Group IIa) of the Periodic Table and/or an element belonging to Group 13 (Group IIIb) of the Periodic Table is further added. This can improve the fluorescent output and energy resolution, allowing its use as a scintillator with reduced variation in fluorescent output due to differences in cerium concentration. The addition amounts are adjusted so that the contents in the produced scintillator single crystal satisfy the contents for a scintillator single crystal according to the first embodiment.

For the single crystal in the production process according to the second embodiment, addition of praseodymium, terbium or thulium to the cerium-activated orthosilicate compound single crystal for coactivation with cerium is not essential, but addition of an element belonging to Group 2 (Group IIa) of the Periodic Table is essential. The addition amounts are adjusted so that the contents in the produced scintillator single crystal satisfy the contents for a scintillator single crystal according to the second embodiment.

The single crystal is therefore highly useful as a scintillator single crystal to be used in a single-crystal scintillation detector (scintillator) for gamma ray or other radiation in the fields of radiology, physics, physiology, chemistry, mineralogy and oil exploration, such as for medical diagnostic positron CT (PET), cosmic radiation observation, underground resource exploration and the like, and it is especially effective for next-generation high performance PET that combines scintillators with different decay times.

The embodiments described above are only preferred embodiments of the invention, and the invention is in no way limited thereto.

The present invention will now be explained in greater detail based on examples and comparative examples, with the understanding that these examples are in no way limitative on the invention.

### Example 1

### Production of Single Crystal

A single crystal was produced by the Czochralski method. First, as the starting materials there were combined lutetium oxide (Lu₂O₃, 99.99 mass % purity), silicon dioxide (SiO₂, 99.9999 mass % purity), cerium oxide (CeO₂, 99.99 mass % purity) and praseodymium oxide (Pr₆O₁₁, 99.99 mass % purity) to a stoichiometric composition of Ln_{2-(x+y+z)}LuₓCe_{y}Lm_{z}SiO₅(Ln=Lu, Lm=Pr, x=1.996, y=0.003, z=0.001), to obtain a total 500 g mixture. There was also weighed out 0.08748 g of calcium carbonate (CaCO₃, 99.99 mass % purity) (corresponding to 0.007 mass % as Ca).

Next, the 500 g of obtained starting mixture and the weighed out calcium carbonate were loaded into an iridium crucible with a diameter of 50 mm, a height of 50 mm and a thickness of 1.5 mm, and heated in a high-frequency induction heating furnace to the melting point of approximately 2100° C. to obtain a melt. The melting point was measured using an electronic optical pyrometer (Pyrostar MODEL UR-U by Chino Corp.).

Next, the end of the lifting rod to which the seed crystal was anchored was placed in the melt for seeding. The shoulder of the single crystal ingot was lifted up at a crystal lifting speed of 1.5 mm/h, and when the diameter reached 25 mm(φ), growth was initiated at the parallel portion at a lifting speed of 1 mm/h for growth of a crystal to the prescribed mass, after which the single crystal was cut off from the melt and cooling was initiated. During growth of the crystal, N₂ was circulated through the growth furnace at 4 L/min. The oxygen concentration in the growth furnace during this time was less than 0.02 vol %. Thus, a single crystal ingot was obtained having a crystal mass of 280 g, a shoulder length of 30 mm and a parallel portion length of 90 mm.

Based on the results of elemental analysis, the obtained single crystal ingot had a Pr segregation coefficient of 0.36, a Ce segregation coefficient of 0.22 and a Ca segregation coefficient of 0.15. The segregation coefficient is represented by formula (4).

Cs/Co=k(1−g)^{k-1} (4)

(Co: solute concentration in melt, Cs: concentration in crystal, k: effective segregation coefficient, g: solidification rate)

A 4×6×20 mm³ sample was cut out from the top of the single crystal ingot obtained in this manner, and 5 arbitrary crystal samples were removed and placed on a platinum sheet and loaded into an electric furnace. The temperature in the electric furnace was raised over a period of about 3-4 hours in an air atmosphere and maintained at 1200° C. for 12 hours, after which it was cooled to room temperature over a period of about 5-8 hours. Each crystal sample was then subjected to chemical etching with phosphoric acid, for mirror surfacing of the entire crystal sample surface. A scintillator single crystal for Example 1 was thus obtained.

### <Measurement of Fluorescent Property>

Polytetrafluoroethylene (PTFE) tape was used as a reflective material to cover all but one of the six 4 mm×6 mm sides of the 4×6×20 mm³ scintillator single crystal (each sample) (this will hereunder be referred to as the “radiation incident side”), i.e. 5 sides. The radiation incident side of each sample which was not covered with PTFE tape was attached to the photomultiplier side (photoelectric conversion side) of a photomultiplier tube (trade name: H7195, by Hamamatsu Photonics, K.K.) using optical grease. Each sample was then irradiated with 662 keV gamma rays using ¹³⁷Cs, and the energy spectrum of each sample was measured to evaluate the fluorescent output and energy resolution of each sample. The energy spectrum was measured with an MCA (trade name Quantum MCA4000, by PGT) while applying a voltage of 1.45 kV to the photomultiplier tube and amplifying the signal from the dynode using a preamplifier (trade name “113”, by ORTEC) and a waveform shaping amplifier (trade name “570”, by ORTEC). The fluorescent decay time was determined by inputting the signal from the anode of the photomultiplier tube to a digital oscilloscope (trade name “TDS5052”, by Tektronix) with an input impedance of 50Ω, averaging the values of 10,000 signals, and calculating from the obtained fluorescence decay curve. Table 1 shows the compositional formula for this example and the results of measuring the fluorescent properties (fluorescent output, energy resolution, fluorescent decay time) as averages for each sample.

The ultraviolet excitation fluorescence property was measured using a fluorescence spectrophotometer (Hitachi F-4500), with an excitation wavelength of 200-400 nm and a fluorescent wavelength of 200-700 nm, all under conditions with a sampling interval of 4 nm, a scan speed of 1200 nm/min, an excitation/fluorescence slit size of 2.5 nm and a PMT (photomultiplier tube) voltage of 400 V. The ratio of the fluorescence intensity at 364 nm as one main excitation wavelength with respect to the fluorescence intensity at 304 nm as another main excitation wavelength (364 nm/304 nm) was calculated at a fluorescent wavelength of 420 nm at which the fluorescent output was approximately maximum, and the obtained values are shown in Table 1.

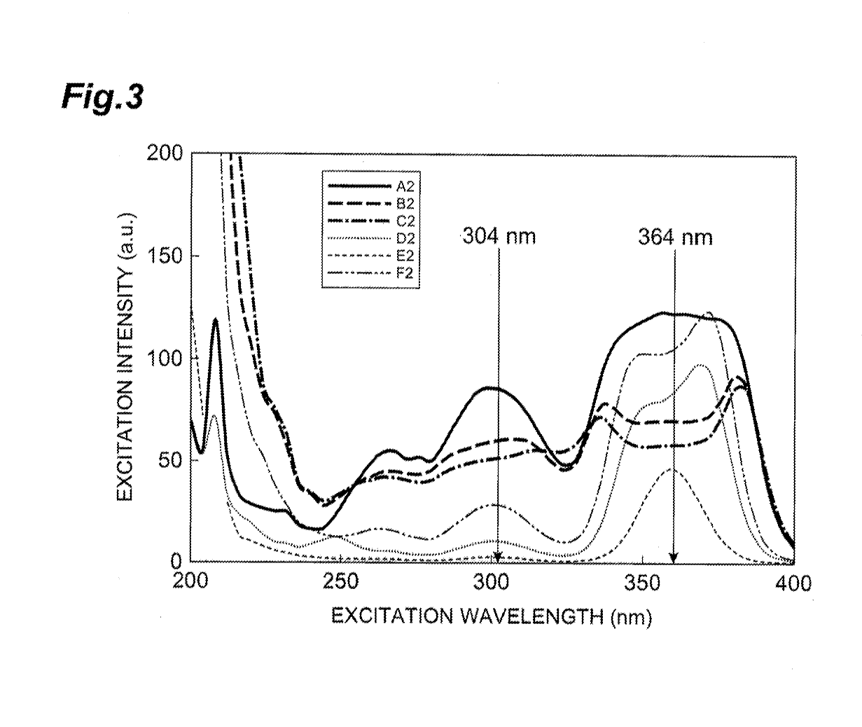

FIG. 3 shows the excitation wavelength spectrum for the wavelength of 420 nm. In FIG. 3, D2 represents Example 1, and A2, B2, C2, E2 and F2 represent Example 13, Example 14, Example 15, Comparative Example 4 and Comparative Example 7, respectively.

### Example 2

A scintillator single crystal for Example 2 was produced in the same manner as Example 1, except that the amounts of lutetium oxide and cerium oxide in the starting material were adjusted so that x=1.996 was x=1.9985 and y=0.003 was y=0.0005. The fluorescent properties of the obtained scintillator single crystal were measured by the same procedure as for Example 1. Table 1 shows the compositional formula for this example and the results of measuring the fluorescent properties as averages for each sample.

### Example 3

A scintillator single crystal for Example 3 was produced in the same manner as Example 1, except that terbium oxide (Tb₄O₇, 99.99 mass % purity) was used instead of praseodymium oxide (Pr₆O₁₁, 99.99 mass % purity) (Lm=Tb) in the starting material. Based on the results of elemental analysis for the obtained single crystal ingot, the Tb segregation coefficient was 0.7, the Ce segregation coefficient was 0.25 and the Ca segregation coefficient was 0.15. The fluorescent properties of the obtained scintillator single crystal were measured by the same procedure as for Example 1. Table 1 shows the compositional formula for this example and the results of measuring the fluorescent properties as averages for each sample.

### Example 4

A scintillator single crystal for Example 4 was produced in the same manner as Example 3, except that the amounts of lutetium oxide and cerium oxide in the starting material were adjusted so that x=1.996 was x=1.9985 and y=0.003 was y=0.0005. The fluorescent properties of the obtained scintillator single crystal were measured by the same procedure as for Example 1. Table 1 shows the compositional formula for this example and the results of measuring the fluorescent properties as averages for each sample.

### Example 5

A scintillator single crystal for Example 5 was produced in the same manner as Example 1, except that thulium oxide (Tm₂O₃, 99.99 mass % purity) was used instead of praseodymium oxide (Pr₆O₁₁, 99.99 mass % purity) (Lm=Tm) in the starting material. Based on the results of elemental analysis for the obtained single crystal ingot, the Tm segregation coefficient was 0.8, the Ce segregation coefficient was 0.26 and the Ca segregation coefficient was 0.15. The fluorescent properties of the obtained scintillator single crystal were measured by the same procedure as for Example 1. Table 1 shows the compositional formula for this example and the results of measuring the fluorescent properties as averages for each sample.

### Example 6

A scintillator single crystal for Example 6 was produced in the same manner as Example 5, except that the amounts of lutetium oxide and cerium oxide in the starting material were adjusted so that x=1.996 was x=1.9985 and y=0.003 was y=0.0005. The fluorescent properties of the obtained scintillator single crystal were measured by the same procedure as for Example 1. Table 1 shows the compositional formula for this example and the results of measuring the fluorescent properties as averages for each sample.

### Example 7

A scintillator single crystal for Example 7 was produced in the same manner as Example 1, except that the starting materials used were gadolinium oxide (Gd₂O₃, 99.99 mass % purity) and terbium oxide (Tb₄O₇, 99.99 mass % purity) for a stoichiometric composition of Ln_{2-(x+y+z)}LuₓCe_{y}Lm_{z}SiO₅ (Ln=Gd, Lm=Tb, x=1.8, y=0.003, z=0.001). The fluorescent properties of the obtained scintillator single crystal were measured by the same procedure as for Example 1. Table 2 shows the compositional formula for this example and the results of measuring the fluorescent properties as averages for each sample.

### Example 8

A scintillator single crystal for Example 8 was produced in the same manner as Example 7, except that the amounts of gadolinium oxide and cerium oxide in the starting material were adjusted so that y=0.003 was y=0.0005. The fluorescent properties of the obtained scintillator single crystal were measured by the same procedure as for Example 1. Table 2 shows the compositional formula for this example and the results of measuring the fluorescent properties as averages for each sample.

### Example 9

A scintillator single crystal for Example 9 was produced in the same manner as Example 1, except that the starting materials used were yttrium oxide (Y₂O₃, 99.99 mass % purity) and terbium oxide (Tb₄O₇, 99.99 mass % purity) for a stoichiometric composition of Ln_{2-(x+y+z)}LuₓCe_{y}Lm_{z}SiO₅ (Ln=Y, Lm=Tb, x=1.8, y=0.003, z=0.001). The fluorescent properties of the obtained scintillator single crystal were measured by the same procedure as for Example 1. Table 3 shows the compositional formula for this example and the results of measuring the fluorescent properties as averages for each sample.

### Example 10

A scintillator single crystal for Example 10 was produced in the same manner as Example 9, except that the amounts of yttrium oxide and cerium oxide in the starting material were adjusted so that y=0.003 was y=0.0005. The fluorescent properties of the obtained scintillator single crystal were measured by the same procedure as for Example 1. Table 3 shows the compositional formula for this example and the results of measuring the fluorescent properties as averages for each sample.

### Example 11

A scintillator single crystal for Example 11 was produced in the same manner as Example 1, except that the starting materials used were gadolinium oxide (Gd₂O₃, 99.99 mass % purity), yttrium oxide (Y₂O₃, 99.99 mass % purity) and terbium oxide (Tb₄O₇, 99.99 mass % purity), for a stoichiometric composition of Gd_{2-(a+x+y+z)}LnₐLuₓCe_{y}Lm_{z}SiO₅ (Ln=Y, Lm=Tb, a=0.06, x=1.86, y=0.003, z=0.001). The fluorescent properties of the obtained scintillator single crystal were measured by the same procedure as for Example 1. Table 4 shows the compositional formula for this example and the results of measuring the fluorescent properties as averages for each sample.

### Example 12

A scintillator single crystal for Example 12 was produced in the same manner as Example 11, except that the amounts of gadolinium oxide and cerium oxide in the starting material were adjusted so that y=0.003 was y=0.0005. The fluorescent properties of the obtained scintillator single crystal were measured by the same procedure as for Example 1. Table 4 shows the compositional formula for this example and the results of measuring the fluorescent properties as averages for each sample.

### Comparative Example 1

A scintillator single crystal for Comparative Example 1 was produced in the same manner as Example 1, except that the starting material included no praseodymium oxide (z=0), and the amount of lutetium oxide was adjusted so that x=1.996 was x=1.997. The fluorescent properties of the obtained scintillator single crystal were measured by the same procedure as for Example 1. Table 1 shows the compositional formula for this example and the results of measuring the fluorescent properties as averages for each sample.

### Comparative Example 2

A scintillator single crystal for Comparative Example 2 was produced in the same manner as Example 2, except that the starting material included no praseodymium oxide (z=0), and the amount of lutetium oxide was adjusted so that x=1.9985 was x=1.9995. The fluorescent properties of the obtained scintillator single crystal were measured by the same procedure as for Example 1. Table 1 shows the compositional formula for this example and the results of measuring the fluorescent properties as averages for each sample.

### Comparative Example 3

A scintillator single crystal for Comparative Example 3 was produced in the same manner as Example 7, except that the starting material included no terbium oxide (z=0), and the amount of gadolinium oxide was adjusted correspondingly. The fluorescent properties of the obtained scintillator single crystal were measured by the same procedure as for Example 1. Table 2 shows the compositional formula for this example and the results of measuring the fluorescent properties as averages for each sample.

### Comparative Example 4

A scintillator single crystal for Comparative Example 4 was produced in the same manner as Example 8, except that the starting material included no terbium oxide (z=0), and the amount of gadolinium oxide was adjusted correspondingly. The fluorescent properties of the obtained scintillator single crystal were measured by the same procedure as for Example 1. Table 2 shows the compositional formula for this example and the results of measuring the fluorescent properties as averages for each sample.

### Comparative Example 5

A scintillator single crystal for Comparative Example 5 was produced in the same manner as Example 9, except that the starting material included no terbium oxide (z=0), and the amount of yttrium oxide was adjusted correspondingly. The fluorescent properties of the obtained scintillator single crystal were measured by the same procedure as for Example 1. Table 3 shows the compositional formula for this example and the results of measuring the fluorescent properties as averages for each sample.

### Comparative Example 6

A scintillator single crystal for Comparative Example 6 was produced in the same manner as Example 10, except that the starting material included no terbium oxide (z=0), and the amount of yttrium oxide was adjusted correspondingly. The fluorescent properties of the obtained scintillator single crystal were measured by the same procedure as for Example 1. Table 3 shows the compositional formula for this example and the results of measuring the fluorescent properties as averages for each sample.

### Comparative Example 7

A scintillator single crystal for Comparative Example 7 was produced in the same manner as Example 11, except that the starting material included no terbium oxide (z=0), and the amount of gadolinium oxide was adjusted correspondingly. The fluorescent properties of the obtained scintillator single crystal were measured by the same procedure as for Example 1. Table 4 shows the compositional formula for this example and the results of measuring the fluorescent properties as averages for each sample.

### Comparative Example 8

A scintillator single crystal for Comparative Example 8 was produced in the same manner as Example 12, except that the starting material included no terbium oxide (z=0), and the amount of gadolinium oxide was adjusted correspondingly. The fluorescent properties of the obtained scintillator single crystal were measured by the same procedure as for Example 1. Table 4 shows the compositional formula for this example and the results of measuring the fluorescent properties as averages for each sample.

### Comparative Example 9

A scintillator single crystal for Comparative Example 9 was produced in the same manner as Example 1, except that erbium oxide (Er₂O₃, 99.99 mass % purity) was used instead of praseodymium oxide (Pr₆O₁₁, 99.99 mass % purity) (Lm=Er) in the starting material. The fluorescent properties of the obtained scintillator single crystal were measured by the same procedure as for Example 1.

Table 1 shows the compositional formula for this example and the results of measuring the fluorescent properties as averages for each sample.

### Comparative Example 10

A scintillator single crystal for Comparative Example 10 was produced in the same manner as Example 10, except that erbium oxide (Er₂O₃, 99.99 mass % purity) was used instead of praseodymium oxide (Pr₆O₁₁, 99.99 mass % purity) (Lm=Er) in the starting material. The fluorescent properties of the obtained scintillator single crystal were measured by the same procedure as for Example 1. Table 1 shows the compositional formula for this example and the results of measuring the fluorescent properties as averages for each sample.

TABLE 1

| | | | | | | | Ca | | | | |
|---|---|---|---|---|---|---|---|---|---|---|---|
| | | | | | | | addition | Fluorescent | Energy | Fluorescent | Fluorescence |
| | Compositional | Crystal | | | | | mass | output | resolution | decay time | intensity ratio |
| | formula | classification | a | x | y | z | (%) | (ch) | (%) | (ns) | (364 nm/304 nm) |
| Example 1 | LuₓCe_{y}Pr_{z}SiO₅ | LSO:Ce,Pr | — | 1.996 | 0.003 | 0.001 | 0.007 | 1455 | 8.43 | 39.4 | 8.9 |
| Example 2 | | | | 1.9985 | 0.0005 | | | 1361 | 8.40 | 33.7 | 7.3 |
| Example 3 | LuₓCe_{y}Tb_{z}SiO₅ | LSO:Ce,Tb | | 1.996 | 0.003 | | | 1517 | 8.07 | 39.3 | — |
| Example 4 | | | | 1.9985 | 0.0005 | | | 1429 | 8.02 | 34.6 | — |
| Example 5 | LuₓCe_{y}Tm_{z}SiO₅ | LSO:Ce,Tm | | 1.996 | 0.003 | | | 1500 | 8.06 | 41.4 | 5.5 |
| Example 6 | | | | 1.9985 | 0.0005 | | | 1357 | 8.17 | 34.0 | — |
| Comp. Ex. 1 | LuₓCe_{y}SiO₅ | LSO:Ce | | 1.997 | 0.003 | 0 | | 1437 | 8.57 | 40.6 | 4.1 |
| Comp. Ex. 2 | | | | 1.9995 | 0.0005 | | | 1288 | 8.92 | 34.8 | 3.5 |
| Comp. Ex. 9 | LuₓCe_{y}Er_{z}SiO₅ | LSO:Ce,Er | | 1.996 | 0.003 | 0.001 | | 1372 | 9.15 | 39.6 | — |
| Comp. Ex.10 | | | | 1.9985 | 0.0005 | | | 1227 | 9.33 | 32.1 | — |

When Examples 1, 3 and 5 are compared with Comparative Example 1, it is seen that Examples 1, 3 and 5 had higher fluorescent outputs and superior energy resolution than Comparative Example 1 (Table 1). That is, coactivation of the fluorescent material with cerium and at least one element selected from among praseodymium, terbium and thulium improved the fluorescent output and energy resolution compared to activation with cerium alone. The same is seen when Examples 2, 4 and 6 are compared with Comparative Example 2 (Table 1). The results of Comparative Examples 9 and 10 which employed activation with erbium, in comparison with Comparative Examples 1 and 2, indicated that the fluorescent output and energy resolution were inferior due to crystal coloration even with coactivation.

TABLE 2

| | | | | | | | Ca | | | | |
|---|---|---|---|---|---|---|---|---|---|---|---|
| | | | | | | | addition | Fluorescent | Energy | Fluorescent | Fluorescence |
| | | Crystal | | | | | mass | output | resolution | decay time | intensity ratio |
| | Compositional formula | classification | a | x | y | z | (%) | (ch) | (%) | (ns) | (364 nm/304 nm) |
| Example 7 | Gd_{2-(x+y+z)}LuₓCe_{y}Tb_{z}SiO₅ | LGSO:Ce,Tb | — | 1.8 | 0.003 | 0.001 | 0.007 | 1375 | 8.38 | 39.9 | — |
| Example 8 | | | | | 0.0005 | | | 1300 | 8.85 | 32.8 | — |
| Comp. Ex. 3 | Gd_{2-(x+y+z)}LuₓCe_{y}SiO₅ | LGSO:Ce | | | 0.003 | 0 | | 1326 | 8.45 | 40.6 | — |
| Comp. Ex. 4 | | | | | 0.0005 | | | 1188 | 9.72 | 35.2 | 15.7 |

When Example 7 is compared with Comparative Example 3, it is seen that Example 7 had higher fluorescent output and also more satisfactory energy resolution (Table 2). When Example 8 is compared with Comparative Example 4, it is seen that Example 8 had higher fluorescent output and also more satisfactory energy resolution (Table 2). With a matrix structure of LGSO, as well as with LSO, it may be concluded that coactivation of the fluorescent material with cerium and at least one element selected from among praseodymium, terbium and thulium improved the fluorescent output and energy resolution.

TABLE 3

| | | Crystal | | | | |
|---|---|---|---|---|---|---|
| | Compositional formula | classification | a | x | y | z |
| Example 9 | Y_{2-(x+y+z)}LuₓCe_{y}Tb_{z}SiO₅ | LYSO:Ce,Tb | — | 1.8 | 0.003 | 0.001 |
| Example 10 | | | | | 0.0005 | |
| Comp. Ex. 5 | Y_{2-(x+y+z)}LuₓCe_{y}SiO₅ | LYSO:Ce | | | 0.003 | 0 |
| Comp. Ex. 6 | | | | | 0.0005 | |

| | | | | | Fluorescence |
|---|---|---|---|---|---|
| | Ca addition | Fluorescent | Energy | Fluorescent | intensity |
| | mass | output | resolution | decay time | ratio |
| | (%) | (ch) | (%) | (ns) | (364 nm/304 nm) |
| Example 9 | 0.007 | 1373 | 8.33 | 39.8 | 5.4 |
| Example 10 | | 1308 | 9.01 | 34.1 | 8.9 |
| Comp. Ex. 5 | | 1329 | 8.61 | 39.8 | — |
| Comp. Ex. 6 | | 1194 | 9.68 | 34.9 | — |

When Example 9 is compared with Comparative Example 5, it is seen that Example 9 had higher fluorescent output and also more satisfactory energy resolution (Table 3). When Example 10 is compared with Comparative Example 6, it is seen that Example 10 had higher fluorescent output and also more satisfactory energy resolution (Table 3). With a matrix structure of LYSO as well, it may be concluded that coactivation of the fluorescent material with cerium and at least one element selected from among praseodymium, terbium and thulium improved the fluorescent output and energy resolution.

TABLE 4

| | | Crystal | | | | |
|---|---|---|---|---|---|---|
| | Compositional formula | classification | a | x | y | z |
| Example 11 | Gd_{2-(a+x+y+z)}YₐLuₓCe_{y}Tb_{z}SiO₅ | LGYSO:Ce,Tb | 0.06 | 1.86 | 0.003 | 0.001 |
| Example 12 | | | | | 0.0005 | |
| Comp. Ex. 7 | Gd_{2-(a+z+y+z)}YₐLuₓCe_{y}SiO₅ | LGYSO:Ce | | | 0.003 | 0 |
| Comp. Ex. 8 | | | | | 0.0005 | |

| | | | | | Fluorescence |
|---|---|---|---|---|---|
| | Ca addition | Fluorescent | Energy | Fluorescent | intensity |
| | mass | output | resolution | decay time | ratio |
| | (%) | (ch) | (%) | (ns) | (364 nm/304 nm) |
| Example 11 | 0.007 | 1450 | 8.08 | 39.4 | — |
| Example 12 | | 1392 | 8.12 | 33.9 | — |
| Comp. Ex. 7 | | 1415 | 8.51 | 40.2 | 3.9 |
| Comp. Ex. 8 | | 1285 | 9.22 | 34.9 | 15.7 |

When Example 11 is compared with Comparative Example 7, it is seen that Example 11 had higher fluorescent output and also more satisfactory energy resolution (Table 4). When Example 12 is compared with Comparative Example 8, it is seen that Example 12 had higher fluorescent output and also more satisfactory energy resolution (Table 4). With a matrix structure of LGYSO as well, it may be concluded that coactivation of the fluorescent material with cerium and at least one element selected from among praseodymium, terbium and thulium improved the fluorescent output and energy resolution.

Table 5 shows the rate of improvement in the fluorescent output by coactivation, with the same cerium concentration (equal y values in the compositional formula). The fluorescent output ratio (%) was calculated, with the fluorescent output value (ch) of the example as the numerator and the fluorescent output value (ch) of the comparative example as the denominator.

TABLE 5

| | Fluorescent | |
|---|---|---|
| (Output [ch]/output [ch]) × 100 | output ratio (%) | y |
| (Example 1)/(Comp. Ex. 1) | 101.3 | 0.003 |
| (Example 3)/(Comp. Ex. 1) | 105.6 | |
| (Example 5)/(Comp. Ex. 1) | 104.4 | |
| (Example 7)/(Comp. Ex. 3) | 103.7 | |
| (Example 9)/(Comp. Ex. 5) | 103.3 | |
| (Example 11)/(Comp. Ex. 7) | 102.5 | |
| Average | 103 | |
| (Example 2)/(Comp. Ex. 2) | 105.7 | 0.0005 |
| (Example 4)/(Comp. Ex. 2) | 110.9 | |
| (Example 6)/(Comp. Ex. 2) | 105.4 | |
| (Example 8)/(Comp. Ex. 4) | 109.4 | |
| (Example 10)/(Comp. Ex. 6) | 108.9 | |
| (Example 12)/(Comp. Ex. 8) | 108.3 | |
| Average | 108 | |

As clearly seen by the results in Table 5, the average value was 103% when y was 0.003 (cerium high concentration end), and the average value was 108% when y was 0.0005 (cerium low concentration end). That is, the cerium low concentration end may be considered to have increased fluorescent output by coactivation.

The fluorescent output ratio (%) was also calculated with the cerium low concentration end as the numerator and the cerium high concentration end as the denominator, for a combination with coactivation of the cerium low concentration end (y=0.0005) and use in DOI-PET, as shown in Table 6.

TABLE 6

| | Fluorescent |
|---|---|
| (Output [ch]/output [ch]) × 100 | output ratio (%) |
| (Comp. Ex. 2)/(Comp. Ex. 1) | 89.6 |
| (Comp. Ex. 4)/(Comp. Ex. 3) | 89.6 |
| (Comp. Ex. 6)/(Comp. Ex. 5) | 89.8 |
| Average | 90 |
| (Example 2)/(Comp. Ex. 1) | 94.7 |
| (Example 4)/(Comp. Ex. 1) | 99.4 |
| (Example 6)/(Comp. Ex. 1) | 94.4 |
| (Example 8)/(Comp. Ex. 3) | 98.0 |
| (Example 10)/(Comp. Ex. 5) | 98.4 |
| (Example 12)/(Comp. Ex. 7) | 97.0 |
| Average | 97 |

As clearly seen by the results in Table 6, the average value was 90% with cerium alone at both the cerium low concentration end and high concentration end, while the average value was 97% with coactivation only at the cerium low concentration end. In other words, coactivation at the cerium low concentration end allows the difference in fluorescent output at the high concentration end to be drastically reduced.

The fluorescent output ratio (%) was also calculated with the cerium low concentration end as the numerator and the cerium high concentration end as the denominator, for a combination with coactivation at both the cerium low concentration end (y=0.0005) and the high concentration end (y=0.003), and use in DOI-PET, as shown in Table 7.

TABLE 7

| | Fluorescent |
|---|---|
| (Output [ch]/output [ch]) × 100 | output ratio (%) |
| (Comp. Ex. 2)/(Comp. Ex. 1) | 89.6 |
| (Comp. Ex. 4)/(Comp. Ex. 3) | 89.6 |
| (Comp. Ex. 6)/(Comp. Ex. 5) | 89.8 |
| Average | 90 |
| (Example 2)/(Example 1) | 93.5 |
| (Example 4)/(Example 3) | 94.2 |
| (Example 6)/(Example 5) | 90.5 |
| (Example 8)/(Example 7) | 94.5 |
| (Example 10)/(Example 9) | 95.3 |
| (Example 12)/(Example 11) | 96.0 |
| Average | 94 |

As clearly seen by the results in Table 7, the average value was 90% with cerium alone at both the cerium low concentration end and high concentration end, while the average value was 94% with coactivation at both the cerium low concentration end and high concentration end. In other words, it is possible to reduce the difference in fluorescent output by combining coactivations.

These results indicate that adding at least one element selected from among praseodymium, terbium and thulium to a cerium-activated orthosilicate compound single crystal, for coactivation of a fluorescent material with cerium, can improve the fluorescent output and energy resolution regardless of the cerium concentration, and can reduce differences in fluorescent properties due to cerium concentration. A scintillator combining coactivation at the cerium low concentration end with activation with cerium alone at the cerium high concentration end, with particularly large increase in fluorescent properties at the cerium low concentration end, can further reduce the difference in fluorescent properties and is highly promising for use in DOI next-generation high performance PET.

### Example 13

A scintillator single crystal for Example 13 was produced in the same manner as Comparative Example 4, except that the amounts of gadolinium oxide and cerium oxide in the starting material were adjusted so that y=0.0005 was y=0.015, and the heat treatment step in an air atmosphere in an electric furnace after cutting the sample to 4×6×20 mm³ was not carried out. The fluorescent properties of the obtained scintillator single crystal were measured by the same procedure as for Example 1. Table 8 shows the compositional formula for this example and the results of measuring the fluorescent properties as averages for each sample.

### Example 14

A scintillator single crystal for Example 14 was produced in the same manner as Comparative Example 7, except that the amounts of gadolinium oxide and cerium oxide in the starting material were adjusted so that y=0.003 was y=0.015, and the heat treatment step in an air atmosphere in an electric furnace after cutting the sample to 4×6×20 mm³ was not carried out. The fluorescent properties of the obtained scintillator single crystal were measured by the same procedure as for Example 1. Table 8 shows the compositional formula for this example and the results of measuring the fluorescent properties as averages for each sample.

### Example 15

A scintillator single crystal for Example 15 was produced in the same manner as Example 11, except that the amounts of gadolinium oxide and cerium oxide in the starting material were adjusted so that y=0.003 was y=0.015 and so that z=0.001 was z=0.0004, and the heat treatment step in an air atmosphere in an electric furnace after cutting the sample to 4×6×20 mm³ was not carried out. The fluorescent properties of the obtained scintillator single crystal were measured by the same procedure as for Example 1. Table 8 shows the compositional formula for this example and the results of measuring the fluorescent properties as averages for each sample.

The measurement results for the fluorescent properties of Example 1 and Comparative Examples 4 and 7 are shown together in Table 8, in comparison with Examples 13-15.

TABLE 8

| | | Crystal | | | | |
|---|---|---|---|---|---|---|
| | Compositional formula | classification | a | x | y | z |
| Example 13 | Gd_{2-(x+y+z)}LuₓCe_{y}SiO₅ | LGSO:Ce | — | 1.8 | 0.015 | 0 |
| Example 14 | Gd_{2-(a+x+y+z)}YₐLuₓCe_{y}SiO₅ | LGYSO:Ce | 0.06 | 1.86 | 0.015 | 0 |
| Example 15 | Gd_{2-(a+x+y+z)}YₐLuₓCe_{y}Tb_{z}SiO₅ | LGYSO:Ce,Tb | 0.06 | 1.86 | 0.015 | 0.0004 |
| Example 1 | LuₓCe_{y}Pr_{z}SiO₅ | LSO:Ce,Pr | — | 1.996 | 0.003 | 0.001 |
| Comp. Ex. 4 | Gd_{2-(x+y+z})LuₓCe_{y}SiO₅ | LGSO:Ce | — | 1.8 | 0.0005 | 0 |
| Comp. Ex. 7 | Gd_{2-(a+x+y+z)}YₐLuₓCe_{y}SiO₅ | LGYSO:Ce | 0.06 | 1.86 | 0.003 | 0 |

| | | | | | Fluorescence |
|---|---|---|---|---|---|
| | Ca addition | Fluorescent | Energy | Fluorescent | intensity |
| | mass | output | resolution | decay time | ratio |
| | (%) | (ch) | (%) | (ns) | (364 nm/304 nm) |
| Example 13 | 0.007 | 1352 | 8.11 | 46.1 | 1.5 |
| Example 14 | 0.007 | 1420 | 8.07 | 45.9 | 1.2 |
| Example 15 | 0.007 | 1450 | 8.15 | 46.0 | 1.3 |
| Example 1 | 0.007 | 1455 | 8.43 | 39.4 | 8.9 |
| Comp. Ex. 4 | 0.007 | 1188 | 9.72 | 35.2 | 15.7 |
| Comp. Ex. 7 | 0.007 | 1415 | 8.51 | 40.2 | 3.9 |

In Example 13 and Example 14 shown in Table 8, measurement of fluorescent properties was with only the cerium activator and a composition with a higher cerium concentration (y=0.015) than the scintillator single crystals of Examples 1-12. The fluorescent decay time was approximately 46 ns, and considering the combinations of Example 13 and Example 8 and of Example 14 and Example 12, the difference in fluorescent decay times was at least 10 ns. In Example 15, measurement of fluorescent properties was done with coactivation with terbium and cerium, and with a composition having a similarly high cerium concentration (y=0.015). The fluorescent decay time was likewise approximately 46 ns, and the fluorescent output was increased. In DOI next-generation high performance PET, the difference in fluorescent decay times of two different scintillators that are combined is ideally at least 10 ns, and therefore a combination of the cerium high concentration end having the composition of Examples 13 and 14 or 15, and the coactivated cerium low concentration end (for example, Example 8 or 12), has an even lower difference in fluorescent output and is suitable for use in DOI next-generation high performance PET.

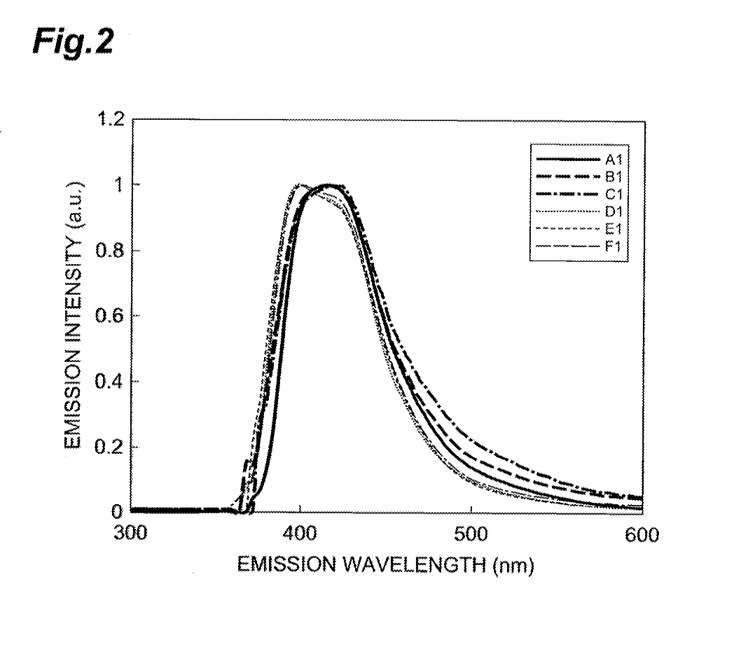

FIG. 2 shows the ultraviolet-excitation fluorescence spectra using ultraviolet rays having an excitation wavelength of 364 nm, for the single crystals of Examples 13, 14, 15 and 1, and Comparative Examples 4 and 7. In FIG. 2, A1 represents Example 13, B1 represents Example 14, C1 represents Example 15, D1 represents Example 1, E1 represents Comparative Example 4 and F1 represents Comparative Example 7. The fluorescence spectra of the single crystals of Examples 13-15 indicate fluorescence with maximum fluorescent output near a wavelength of 420 nm. In Example 13, Example 14 and Example 15 which had compositions with high cerium concentrations (y=0.015), the proportion of the fluorescent long wavelength component near 500 nm was increased in the fluorescence spectra shown in FIG. 2. With this change in properties, excellent fluorescent properties may be exhibited by combination with a semiconductor detector such as an avalanche photodiode with a maximum sensitivity wavelength of 500 nm or greater.

What is claimed is:

1. A scintillator single crystal comprising a cerium-activated orthosilicate compound represented by formula (1).
Gd_{2-(a+x+y+z)}LnₐLuₓCe_{y}Lm_{z}SiO₅ (1)
(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

2. A scintillator single crystal according to claim 1, wherein Ln is Gd, a represents a value of greater than 0 and less than 1, and Lm is at least one element selected from Tb and Tm.

3. A scintillator single crystal according to claim 1, wherein Ln is Y and a represents a value of greater than 0 and less than 1.

4. A scintillator single crystal according to claim 1, wherein Ln is Y, a represents a value of greater than 0 and no greater than 0.2, and x represents a value of greater than 1.6 and less than 2.

5. A scintillator single crystal according to claim 1, which contains an added element which is at least one element selected from among elements belonging to Group 2 (Group IIa) of the Periodic Table, at 0.00005-0.1 mass % based on the total mass of the single crystal.

6. A scintillator single crystal according to claim 1, which contains an added element which is at least one element selected from among elements belonging to Group 13 (Group IIIb) of the Periodic Table, at 0.00005-0.1 mass % based on the total mass of the single crystal.

7. A heat treatment process for production of a scintillator single crystal according to claim 1,
wherein a single crystal body is grown using a starting material comprising the constituent element for a scintillator single crystal containing a cerium-activated orthosilicate compound represented by the following formula (1), and is heat treated at a temperature of 700-1500° C. in an oxygen-containing atmosphere.
Gd_{2-(a+x+y+z)}LnₐLuₓCe_{y}Lm_{z}SiO₅ (1)
(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

8. A process for production of a scintillator single crystal according to claim 1, the process comprising:
a step of preparing a starting material comprising the constituent element for a scintillator single crystal containing a cerium-activated orthosilicate compound represented by the following formula (1), and growing a single crystal body by the Czochralski method, and
a step of heat treating the single crystal body at a temperature of 700-1500° C. in an oxygen-containing atmosphere.
Gd_{2-(a+x+y+z)}LnₐLuₓCe_{y}Lm_{z}SiO₅ (1)
(In formula (1), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0 and no greater than 0.01, and z represents a value of greater than 0 and no greater than 0.01. The value of a+x+y+z is no greater than 2.)

9. A scintillator single crystal comprising a cerium-activated orthosilicate compound represented by the following formula (2), which contains at least one added element selected from among elements belonging to Group 2 (group IIa) of the Periodic Table at 0.00005-0.1 mass % based on the total mass of the single crystal, and wherein the ratio of the fluorescence intensity at an excitation wavelength of 364 nm with respect to the fluorescence intensity at an excitation wavelength of 304 nm (364 nm/304 nm), at a fluorescent wavelength of 420 nm, is less than 3.
Gd_{2-(a+x+y+z)}LnₐLuₓCe_{y}Lm_{z}SiO₅ (2)
(In formula (2), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0.01 and no greater than 0.03, and z represents a value of at least 0 and no greater than 0.01. The value of a+x+y+z is no greater than 2.)

10. A process for production of a scintillator single crystal according to claim 9, the process comprising:
a step of preparing a starting material comprising the constituent element for a scintillator single crystal containing a cerium-activated orthosilicate compound represented by formula (2), and growing a single crystal body by the Czochralski method.
Gd_{2-(a+x+y+z)}LnₐLuₓCe_{y}Lm_{z}SiO₅ (2)
(In formula (2), Lm represents at least one element selected from among Pr, Tb and Tm, Ln represents at least one element selected from among lanthanoid elements excluding Pr, Tb and Tm, and Sc and Y, a represents a value of at least 0 and less than 1, x represents a value of greater than 1 and less than 2, y represents a value of greater than 0.01 and no greater than 0.03, and z represents a value of at least 0 and no greater than 0.01. The value of a+x+y+z is no greater than 2.)
